(19) United States
(12) Patent Application Publication
(10) Pub. No.: US 2010/0111119 A1
(43) Pub. Date: May 6, 2010

(54) EXTERNAL RESONATOR TYPE WAVELENGTH VARIABLE SEMICONDUCTOR LASER

(76) Inventors: Kenji Sato, Tokyo (JP); Kenji Mizutani, Tokyo (JP); Shinya Sudo, Tokyo (JP); Koji Kudo, Tokyo (JP)

Correspondence Address: Mr. Jackson Chen, 6535 N. STATE HWY 161, IRVING, TX, 75039, US

(21) Appl. No.: 12/593,513

(22) PCT Filed: Feb. 6, 2008
(86) PCT No.: PCT/JP2008/051930

§ 371 Date: Dec. 7, 2009

(30) Foreign Application Priority Data
Mar. 28, 2007 (JP) 2007-084642

(51) Int. Cl. H01S 5/06; H01S 5/14

(52) U.S. Cl. 372/20; 372/43.01; 372/38.01

(57) ABSTRACT

In an external resonator type semiconductor wavelength tunable laser apparatus using a wavelength tunable mirror or a wavelength tunable filter which uses a refractive index change of liquid crystal, a resonant frequency is set as FR, when a response of the refractive index change to a drive voltage frequency of liquid crystal becomes maximum. A frequency F1 of a drive AC power supply voltage to control the refractive index of liquid crystal is set to a frequency largely different from FR. A wavelength tunable mirror or a wavelength tunable filter is driven with a signal in which a dither AC signal F2 of a frequency close to the FR and an AC power supply voltage are superimposed. A PD to monitor a light output from the laser controls an amplitude of the drive AC power voltage such that an amplitude of the dither AC signal F2 become minimum. Thus, high laser mode stability is realized.

### TECHNICAL FIELD

The present invention relates to a mechanism for selecting a desired laser oscillation wavelength in a wavelength division multiplexing type optical communication system. More particularly, the present invention relates to a wavelength tunable laser apparatus which has an external resonator structure using a tunable filter, and a control apparatus of an optical output module that has an external resonator type wavelength tunable laser apparatus.

This patent application claims a priority on convention based on Japan Patent Application No. 2007-084642 filed on Mar. 28, 2007. The disclosure thereof is incorporated herein by reference.

### BACKGROUND ART

In recent years, in association with the rapid popularization of the Internet, a larger capacity of communication traffic is required. In response to this request, the improvement of a transmission rate per system one channel and the increase of the number of channels through employment of wavelength division multiplexing (hereinafter, to be referred to as “WDM”) are advanced. The WDM is a technique that can transmit a plurality of optical signals assigned to carriers of different wavelengths (channels) at a same time, and the communication capacity can be increased according to the number of the channels. For example, by carrying out a modulation at 10 gigabits/second per channel and transmitting signals for 100 channels by a single common optical fiber, the communication capacity of 1 terabits/second can be attained.

As a wavelength band used in a middle or long distance optical communication in the recent years, a C band (between 1530 and 1570 nm) is widely used, which can be amplified by an optical fiber amplifier (an erbium-doped fiber amplifier, hereinafter, to be referred to as “EDFA”). Usually, laser apparatuses of the respective wavelengths are prepared for the standard channels used in the optical communication. Thus, the laser apparatuses of 100 kinds are required for 100 channels. Management of the laser apparatuses of many kinds causes the increases in stock cost and inventory cost. From the above, in the middle or long distance communication, the realization of practical use of the wavelength tunable laser apparatus is desired in which the C band as a wavelength band amplifiable by the EDFA can be entirely covered by a single laser apparatus. If the entire C band can be covered by the single laser apparatus, it is sufficient to deal with the apparatus of one kind. Thus, the costs of stock management and stocktaking can be largely reduced in a manufacturing side and a user side.

On the other hand, the realization of a flexible network is desired in which a pass can be dynamically set according to increase or decrease in traffic and any trouble, and also the infrastructure improvement of a network allowing the provision of further various services is desired. In order to establish a photonic network having a high capacity, a high functionality and a high reliability as mentioned above, a technique for freely controlling the wavelength is essential. Thus, a wavelength tunable laser has become a very important key device.

A first conventional example (Japanese Patent Application Publication (JP-P2003-023208A) describes a wavelength tunable laser technique according to such a request. In this technique, a plurality of distributed feedback (hereinafter, to be referred to as “DFB”) lasers are arrayed in parallel, and the oscillation wavelengths of the respective DFB lasers are shifted in advance. In order to roughly adjust the wavelength, the laser is switched. Moreover, in order to finely adjust the wavelength, a refractive index change based on a temperature is used.

However, the wavelength tunable laser disclosed in the first conventional example involves the following problems. In this wavelength tunable laser, an output port is coupled to one optical fiber. Thus, an optical coupler for integrating the output ports of the respective DFB lasers into one is required. For this reason, when the number of DFB lasers in parallel is increased, a loss in the optical coupler increases. That is, the wavelength tunable range and the optical output are in the relation of tradeoff.

Here, in the DFB laser based wavelength tunable laser, the laser wavelength can be finely adjusted by controlling the temperature. Thus, there is a merit that this can be combined with a wavelength locker described in a second conventional example (Japanese Patent Application Publication (JP-P2001-257419A). The wavelength locker is an etalon type filter having periodic transmission amplitude on a frequency axis. Near the center of a transmission frequency band, the transmission light intensity of the etalon type filter sensitively changes depending on a laser frequency (laser wavelength). For this reason, by detecting the transmission light intensity by use of a monitor current of a photo-detector element, it can be tuned to a desired laser frequency. In this way, the combination of the DFB laser and the wavelength locker provides a scheme for locking the laser wavelength to a standard channel wavelength in a high precision.

On the other hand, as the wavelength tunable laser that satisfies a request of free control of the wavelength without the above-mentioned tradeoff relation, an external resonator type wavelength tunable laser was proposed. In this technique, the external resonator is provided with a semiconductor optical amplifier and an external reflection mirror. Then, optical devices such as a wavelength tunable filter and a wavelength tunable mirror are inserted into the external resonator. Consequently, the wavelength tunable laser having a desirable wavelength selection property is provided. This external resonator type wavelength tunable laser is vigorously researched and developed because the wavelength tunable width is relatively easily obtained to cover the entire C band.

In the external resonator type wavelength tunable laser, most of its basic properties are determined by the wavelength tunable filter or wavelength tunable mirror inserted into the resonator. For this reason, various wavelength tunable filters or wavelength tunable mirrors having the excellent properties have been developed. As the wavelength tunable filter, the following techniques are known. A third conventional example (Japanese Patent Application Publication (JP-A-Heisei 4-69987) describes a filter for rotating an etalon. A fourth conventional example (Japanese Patent Application Publication (JP-A-Heisei 5-48200)) describes a filter for rotating a diffraction grating. A fifth conventional example (Japanese Patent Application Publication (JP-P2000-261086A)) describes an acoustic optical filter and a dielectric filter. As the wavelength tunable mirror, a sixth conventional example (U.S. Pat. No. 6,215,928B1) describes an electric control type wavelength tunable mirror in which an external mirror itself has a wavelength tunable property.

There are various methods of configuring the external resonator type wavelength tunable laser by using the foregoing wavelength tunable filter or wavelength tunable mirror. For example, a seventh conventional example (U.S. Pat. No. 6,526,071B1) discloses a configuration that includes a semiconductor optical amplifier, an etalon and a wavelength tunable filter. According to it, the wavelength tunable filter has a relatively wide transmission bandwidth. Thus, even if the laser resonator is configured only by it, a laser mode is not stabilized. For this reason, since the etalon having the transmission bandwidth narrower than the wavelength tunable filter is inserted into the laser resonator, the laser mode can be stabilized. Moreover, since the wavelength tunable filter has the wide transmission bandwidth, this is relatively insensitive to the precision of its transmission peak wavelength. Thus, a merit that the wavelength tunable filter can be controlled in an open loop is also indicated. That is, according to the description of this conventional example, once the wavelength tunable filter is set, a feedback control from the operation state of the wavelength tunable filter is not carried out.

Also, in the configuration disclosed in the seventh conventional example, the etalon inside the laser resonator acts as a wavelength selecting filter having a periodic transmission property on a frequency axis. At this time, the transmission peak wavelength is fixed. Thus, when a laser oscillation mode is adjusted to the transmission peak wavelength, a transmission rate of the wavelength selecting filter is maximum, and an optical loss inside the laser resonator is minimum. Also, since the transmission rate in a sub mode can be minimized simultaneously, the mode stabilization can be attained.

In order to perform a control in such a manner that the laser oscillation mode is adjusted to the transmission peak wavelength of the wavelength selecting filter, a control method of carrying out a phase adjustment inside the laser resonator is known. The phase adjustment is to effectively change an optical length (Refractive Index n×Actual Length L) of the laser resonator. Specifically, the following two methods are arisen: (1) a material that can control a refractive index such as a semiconductor is arranged inside the laser resonator; and (2) a mechanical method is used to change the actual optical length L.

As a configuration that a phase adjusting mechanism for changing a refractive index of a semiconductor is added, there are the examples of the configuration disclosed in the fifth conventional example and a configuration disclosed in the following tenth conventional example (“Full C-band external cavity wavelength tunable laser using a liquid-crystal-based tunable mirror” (IEEE Photonic Technology Letters, 2005, Vol. 17, Page 681) by J. De Merlier, etc.). They are effective to accomplish a light source of a higher performance. Those techniques employ the etalon as the wavelength selecting filter, similarly to the seventh conventional example. However, they differ from the seventh conventional example in the configuration of the wavelength tunable filter. In the fifth conventional example, the acoustic optical filter and the reflection mirror are combined as the wavelength tunable filter. On the other hand, in the tenth conventional example, an electric control type wavelength tunable mirror using a refractive index change in a liquid crystal is used.

The principle of the wavelength selecting operation according to the external resonator type wavelength tunable laser configured in this way will be described below in brief with reference to FIGS. 1 and 2A to 2D. FIG. 1 is a side view showing the configuration of a conventional external resonator type wavelength tunable laser apparatus. FIGS. 2A, to 2D are diagrams showing a laser oscillation mode of the external resonator type wavelength tunable laser apparatus shown in FIG. 1. FIG. 1 shows a semiconductor device 51, a semiconductor optical amplifier 52, a low reflection coating facet 53, a non-reflection coating facet 54, a collimating lens 55, an etalon 56, a wavelength tunable filter 57, a total reflection mirror 58, a sub carrier 59 and a temperature controller 101. The external resonator is composed of the low reflection coating facet 53, the semiconductor optical amplifier 52, the non-reflection coating facet 54, the collimating lens 55, the etalon 56, the wavelength tunable filter 57 and the total reflection mirror 58. FIG. 2A shows the transmission characteristic of the wavelength tunable filter 57. FIG. 2B shows the transmission characteristic of the etalon 56. FIG. 2C shows a Fabry Perot mode of the external resonator. FIG. 2D shows a laser oscillation mode of the external resonator.

The light emitted from the semiconductor optical amplifier 52 serving as a gain medium includes many Fabry Perot modes 63 that depend on the entire length of the external resonator, as shown in FIG. 2C. Among those modes, only a plurality of modes that coincide with the period of a periodic transmission band 62 (shown in FIG. 2B) of the etalon 56 serving as the wavelength selecting filter are selected by and passed through the wavelength selecting filter. At this time, the Fabry Perot mode that cannot transmit through the wavelength selecting filter is suppressed. Thus, when the frequency interval between the Fabry Perot modes is relatively narrow, namely, even when the entire length of the external resonator is relatively long, the sub mode except the channel can be easily suppressed.

Next, only one from the plurality of modes which have transmitted through the wavelength selecting filter is selected by the wavelength tunable filter 57 indicating a transmission characteristic 61 as shown in FIG. 2A, and transmits through the wavelength tunable filter 57. FIG. 2D shows a mode 64 which has transmitted through the wavelength tunable filter 57. The light having transmitted through the wavelength tunable filter 57 is reflected by the total reflection mirror 58 and finally returned to the semiconductor optical amplifier 52. In this way, the feedback loop is configured. According to the configuration shown in FIG. 1, the wavelength tunable laser whose mode stability is high can be attained relatively easily, and the desired wavelength selection property can be attained by the relatively simple control.

In the configuration shown in FIG. 1, the periodic wavelength of the wavelength selecting filter is fixed, and the wavelength of its transmission peak is coincident with the wavelength of the standard channel for an optical communication. In the configuration shown in FIG. 1, the wavelength selecting filter is arranged inside the external resonator. Thus, the wavelength locker is not required although it is required in the wavelength tunable DFB laser in order to obtain the wavelength precision within the channel precision of the wavelength selecting filter.

In the laser of this type, the transmission peak wavelength of the etalon inside the resonator coincides with an ITU (International Telecommunication Union) grid serving as a standard channel in advance. Thus, it is required to perform a control such that the laser oscillation wavelength is made to coincident with this etalon transmission wavelength by carrying out the phase adjustment. Typically, this etalon is most unlikely to be deteriorated among the installed components. Thus, when the phase adjustment is carried out such that the laser wavelength always coincides with its peak, the oscillation wavelength can be kept constant, even if the semiconductor is deteriorated. This phase adjustment is usually performed by a method referred to as a dither control. In the dither control, a low frequency modulation signal (dither) is superimposed on the DC component (bias) of a phase adjustment current. Then, a laser light output is monitored, and the DC component (bias) of the phase current is feedback controlled such that the amplitude of the modulation signal of the optical output becomes minimum. With such a control, the normal phase adjustment is always executed even if the semiconductor device is deteriorated.

### DISCLOSURE OF INVENTION

However, in the external resonator type wavelength tunable lasers disclosed in the fifth, seventh and tenth conventional examples, there are the following problems because the open loop control was assumed for the wavelength tunable filter or the wavelength tunable mirror. They are because under a certain condition, the laser oscillation mode is likely to be unstable and strict under an actual use environment. Their details will be described below.

The first reason why the laser oscillation mode of the external resonator type wavelength tunable laser is likely to be unstable is in that the external environment temperature is changed in the actual use environment. When the environment temperature outside the laser is changed, the temperature of the wavelength tunable filter or wavelength tunable mirror is increased due to the influence of peripheral heat to change the property so as to lose an initially set state, even if the laser is controlled to a constant temperature. In this way, when the property of the wavelength tunable filter or wavelength tunable mirror is changed, its transmission peak wavelength is changed. This results in the problems that the laser light output is decreased, and the laser mode becomes unstable or is mode-hopped to a near channel wavelength.

Also, the second reason why the laser oscillation mode of the external resonator type wavelength tunable laser is likely to become unstable is in that the wavelength tunable filter or the wavelength tunable mirror is deteriorated with a time. When the wavelength tunable filter or the wavelength tunable mirror is used for a long time such as several tens of thousands of hours, they are slightly deteriorated due to abrasion deterioration. Although depending on the wavelength varying principle, in the wavelength tunable mirror of a liquid crystal type described in the tenth conventional example, the liquid crystal is gradually deteriorated, and the initial set state is lost. Similarly to the first reason, when the property of the wavelength tunable filter or wavelength tunable mirror is changed, its transmission peak wavelength is changed. This results in the problems that the laser light output is decreased, and the laser mode becomes unstable or is mode-hopped to a near-channel wavelength.

Moreover, there is a state in which the laser oscillation mode of the external resonator type wavelength tunable laser is likely to be especially unstable. The fifth conventional example discloses that the transmission bandwidth of the wavelength tunable filter is wider than the transmission bandwidth of the wavelength selecting filter. In particular, when the transmission bandwidth of the wavelength tunable filter is wider than the wavelength channel interval determined by the wavelength selecting filter, the laser mode becomes further unstable. This will be described below in detail with reference to FIG. 7.

FIG. 3 shows the worst value of a side mode suppression ratio (hereinafter, to be referred to as “SMSR”) of the laser, when the transmission peak wavelength of the wavelength tunable filter is varied for the transmission bandwidth of the wavelength tunable filter. Here, the SMSR is defined by a power ratio between the optical output of the mode mainly oscillated in the laser and the optical output of the laser mode of the next highest optical output, and this is an index typically indicating the mode stability of the laser. When the bandwidth of the wavelength tunable filter is wide, the SMSR worst value when the transmission peak wavelength is fluctuated due to the foregoing two factors is known to be further deteriorated. For example, when the wavelength channel interval is 50 GHz, the SMSR can endure the practical use in the bandwidth of the wavelength tunable filter between the bandwidth (for example, 10 GHz) of the wavelength selecting filter and the wavelength channel interval (50 GHz). However, in the bandwidth wider than the wavelength channel interval (50 GHz), it is known that the possibility of the mode hop to the adjacent channel becomes high and the SMSR is deteriorated. The deterioration in this SMSR cannot be avoided only by the structure disclosed in the fifth conventional example.

When the transmission bandwidth of the wavelength tunable filter or wavelength tunable mirror is made narrow in order to make the SMSR high, a different problem occurs. That is, the manufacturing cost of the wavelength tunable filter or wavelength tunable mirror becomes high. Typically, the wavelength varying operation and the attainment of the narrow bandwidth are in the relation of tradeoff. Thus, when the wavelength varying operation for covering the entire C band is attained, the transmission bandwidth trends to be made wide, and when it is tried to be made narrow, the manufacturing yield is decreased, thereby increasing the cost. Thus, at present, the transmission band of the wavelength tunable filter or wavelength tunable mirror is equal to or wider than the wavelength channel interval at most.

As the idea for partially solving the above problems, an external resonator type wavelength tunable laser is disclosed in an eighth conventional example (international publication number WO2006-008873A1). The external resonator type wavelength tunable laser in this eighth conventional example describes a relation a laser mode interval determined by a laser resonator configured between an output side end surface of a semiconductor optical amplifier and a surface of a wavelength tunable mirror, and a channel interval determined by an interval of a wavelength selecting filter. In particular, when j=2 in an equation (2) of the eighth conventional example, in a channel adjacent to a channel of a main mode of a laser, a laser phase condition is not satisfied, and a laser mode is stabilized. Thus, the problems of the foregoing SMSR deterioration can be somewhat solved. Hereinafter, this condition is referred to as an asynchronous mode.

Here, it is effective to feedback-control the state of the wavelength tunable filter or wavelength tunable mirror. However, depending on the operation principle of the wavelength tunable filter or wavelength tunable mirror, the feedback control was difficult. In particular, in the wavelength tunable filter that uses the refractive index change in the liquid crystal, as disclosed in the tenth conventional example, the motion of a liquid crystal molecule is slow. Thus, it is difficult to apply the dither that is used in the phase adjustment. Thus, there was not an effective feedback control method until now. A ninth conventional example (Japan Patent No. 3,104,715) discloses a feedback control technique for maximizing a transmission factor of a liquid crystal wavelength tunable filter. This uses two different oscillators, generates signals of two different frequencies, and superimposes them and then drives the liquid crystal. Consequently, the transmission wavelength of the wavelength tunable filter is controlled. Here, a first frequency is 10 kHz and used to drive the liquid crystal, and a second frequency is 10 Hz and used to monitor the state. However, the response property of the liquid crystal was not considered, and it was not driven by an effective frequency signal.

The present invention relates to a wavelength tunable filter or wavelength tunable mirror that is used as a configuration part of the external resonator type wavelength tunable laser, and especially uses a refractive index change in liquid crystal and provides an effective control circuit by maximizing the response property of the liquid crystal.

In the structure of the external resonator wavelength tunable laser disclosed in the eighth conventional example, the foregoing problems are somewhat improved over the fifth conventional example. However, the external resonator wavelength tunable laser disclosed in the eighth conventional example exhibits the same tendency as the structure of the fifth conventional example in the point that the SMSR of the laser is deteriorated when a material is used in which the transmission bandwidth of the wavelength tunable filter or the reflection bandwidth of the wavelength tunable mirror is wide. In FIG. 3, the SMSR worst value in the eighth conventional example is improved by several decibels as compared with that of the fifth conventional example. However, as for the bandwidth of the wavelength tunable filter or wavelength tunable mirror, only the bandwidth wider than the channel interval can be usually used, although depending on the wavelength varying principle. Actually, the laser can be attained only in the situation in which the SMSR is decreased. Therefore, it is difficult to say that the problems have been perfectly solved.

An object of the present invention is to provide an external resonator type wavelength tunable laser apparatus, which can solve the foregoing problems and attain a high laser mode stability for a long time, even if there are a change in external environment temperature or the aged deterioration of the wavelength tunable filter or wavelength tunable mirror and this is configured by using the wavelength tunable filter whose original transmission bandwidth is wide.

An external resonator type wavelength tunable semiconductor laser according to the present invention contains a semiconductor laser and an external resonator for resonating a laser light outputted from the semiconductor laser. The external resonator contains a wavelength tunable mirror or wavelength tunable filter that has liquid crystal whose refractive index is changed in response to an applied voltage and which is arranged in an optical path of the laser light. The external resonator type wavelength tunable semiconductor laser further contains a dither signal generator for generating a dither signal of a first frequency F1 close to the resonant frequency of the liquid crystal; an AC driving power supply for generating a refractive index control signal of a second frequency F2 in which an absolute value of a deviation from the resonant frequency is greater than the first frequency F1 and superimposing the refractive index control signal and the dither signal and then applying to the wavelength tunable mirror or wavelength tunable filter; and a control unit for detecting an optical output of the laser light and carrying out a feedback control to control the amplitude of the voltage generated by the AC driving power supply such that the amplitude of a component resulting from the dither signal included in the optical output is minimized.

According to the present invention, in the external resonator type wavelength tunable laser apparatus that contains the external resonator which includes a semiconductor optical amplifier and feedbacks external light to perform a laser oscillation operation, the state of the wavelength tunable filter or wavelength tunable mirror which uses the refractive index change in the liquid crystal is feedback-controlled at a practically sufficient rate by using a signal close to a resonant frequency of the liquid crystal, and the following effects can be consequently obtained.

The first effect is in the attainment of the external resonator type wavelength tunable laser apparatus of a high optical output operation, in which the mode stability of the laser is high. This is because the operational state of the wavelength tunable filter or wavelength tunable mirror using the liquid crystal is monitored, and the feedback control is carried out such that a loss is always minimum for a main mode and consequently the loss inside the external resonator is reduced as small as possible, and the laser mode is also considered. The drive current can be decreased, as compared with the external resonator type wavelength tunable laser apparatus that does not have the configuration of the present invention, under the same optical output.

The second effect is in that the precision of the laser wavelength can be kept even for the change in environment temperature. This is because the relatively slow rate change such as the temperature change can be followed by the control so that the wavelength tunable filter is always optimal since the feedback control is performed on the liquid crystal at the sufficiently high rate.

The third effect is in that the wavelength precision of the laser can be held high even if the laser is used for a long time. This is because the feedback control can be carried out to be always optimal by following its change even if the wavelength tunable filter using the liquid crystal is deteriorated with age for the long time.

The fourth effect lies in the fact that the manufacturing cost can be cheapened because the wavelength tunable filter or wavelength tunable mirror whose transmission bandwidth is relatively wide can be used. This is because, when the transmission bandwidth of the wavelength tunable filter or wavelength tunable mirror is tried to be made narrow, the manufacturing yield is decreased, thereby increasing the manufacturing cost.

With the first to fourth effects, it is possible to attain the external resonator type wavelength tunable laser apparatus, in which for the environmental change and the aged deterioration, the laser mode is stable, the output is high, the channel wavelength precision is high, and the cost is low.

### BRIEF DESCRIPTION OF DRAWINGS

FIG. 1 is a side view showing a configuration of an external resonator type wavelength tunable laser apparatus in a conventional example;

FIG. 2A shows a transmission characteristic of a wavelength tunable filter, in order to show the laser oscillation mode of the external resonator type wavelength tunable laser apparatus in FIG. 1;

FIG. 2B shows a transmission characteristic of an etalon, in order to show the laser oscillation mode of the external resonator type wavelength tunable laser apparatus in FIG. 1;

FIG. 2C shows a Fabry Perot mode of the external resonator, in order to show the laser oscillation mode of the external resonator type wavelength tunable laser apparatus in FIG. 1;

FIG. 2D shows the laser oscillation mode of the external resonator, in order to show the laser oscillation mode of the external resonator type wavelength tunable laser apparatus in FIG. 1;

FIG. 3 is a diagram showing a relation of a transmission bandwidth of the wavelength tunable mirror or wavelength tunable filter in seventh and eighth conventional samples and the worst value of SMSR;

FIG. 4 is a block diagram showing a configuration of an external resonator type wavelength tunable laser apparatus and a control apparatus in a first exemplary embodiment of the present invention;

FIG. 5 shows a frequency response of liquid crystal;

FIG. 6A is a diagram showing a reflection intensity to a drive AC voltage V1 of a liquid crystal wavelength tunable mirror, in the first exemplary embodiment of the present invention;

FIG. 6B is a diagram showing a laser light output to a drive AC voltage V1 of a liquid crystal wavelength tunable mirror, in the first exemplary embodiment of the present invention;

FIG. 7 is a block diagram showing another configuration of the external resonator type wavelength tunable laser apparatus with a control apparatus in the first exemplary embodiment of the present invention;

FIG. 8 is a block diagram showing a configuration of the external resonator type wavelength tunable laser apparatus with the control apparatus in a second exemplary embodiment of the present invention;

FIG. 9 is a block diagram showing a configuration of the external resonator type wavelength tunable laser apparatus with the control apparatus in a third exemplary embodiment of the present invention; and

FIG. 10 is a diagram showing a relation of the transmission bandwidth of the wavelength tunable mirror or wavelength tunable filter and the worst value of the SMSR, in the present invention and the seventh and eighth conventional examples.

### BEST MODE FOR CARRYING OUT THE INVENTION

### First Exemplary Embodiment

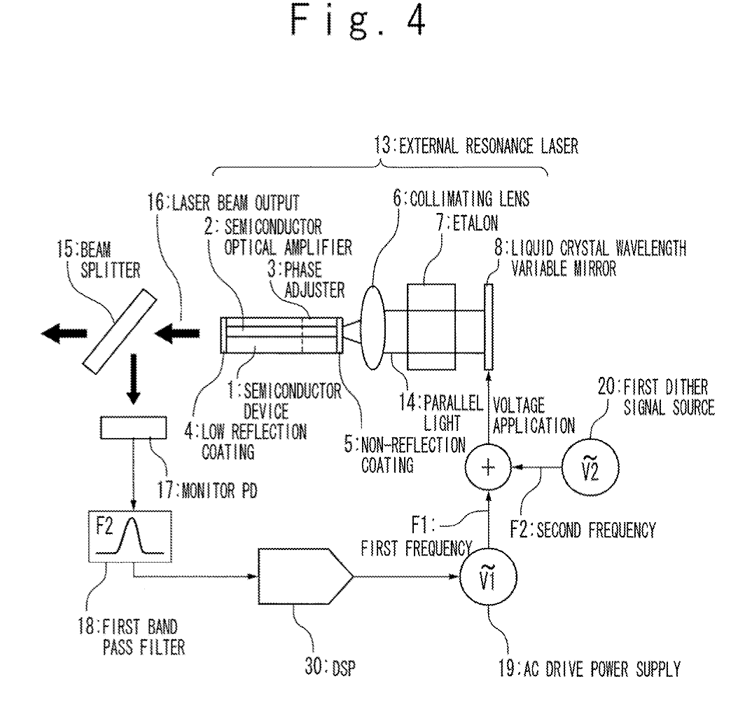

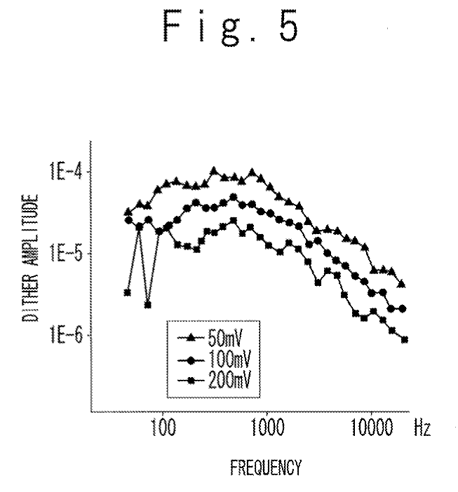

Exemplary Embodiments of the present invention will be described below with reference to the drawings. FIG. 4 is a block diagram showing a configuration of an external resonator type wavelength tunable laser apparatus in the first exemplary embodiment of the present invention. In this exemplary embodiment, an etalon is employed as a wavelength selecting filter, whose transmission characteristic is periodic within the wavelength bandwidth to be used. A device is employed as a wavelength tunable mirror, whose reflection property is not periodic within the wavelength bandwidth that is used in a voltage application type using a refractive index change in liquid crystal. As shown in FIG. 4, the external resonator type wavelength tunable laser apparatus in this exemplary embodiment contains a semiconductor device 1 including a semiconductor optical amplifier 2, a collimating lens 6, an etalon 7 and a liquid crystal wavelength tunable mirror 8. An external resonator type wavelength tunable laser control apparatus in this exemplary embodiment monitors a part of an optical output of the external resonator type wavelength tunable laser apparatus and analyzes a monitor signal by a digital signal processor (DSP) 30 and consequently feedback-controls the liquid crystal wavelength tunable mirror 8. The detail will be described below.

The semiconductor device 1 is formed such that a phase adjuster 3 serving as a passive element is integrated on the semiconductor optical amplifier 2 serving as an active element. In this exemplary embodiment, the laser light is outputted from the left end surface of the semiconductor optical amplifier 2. A low reflection coating 4 whose reflectivity is between 1 and 10% is performed on the left end surface of this semiconductor optical amplifier 2. On the other hand, a non-reflection coating 5 whose reflectivity is 1% or less is performed on the right end surface of the phase adjustment region 3. An external resonator 20 is configured from the low reflection coating 4, the semiconductor optical amplifier 2, the phase adjusting region 3, the non-reflection coating 5, the collimating lens 6, the etalon 7 and the liquid crystal wavelength tunable mirror 8. In this exemplary embodiment, the end surface of the semiconductor optical amplifier 2 on the side opposite to the phase adjuster 3 is the optical output side.

In the semiconductor optical amplifier 2 serving as an active element, a multiple quantum well (MQW) is formed. By the multiple quantum well, the light is generated and amplified in response to the injection of a current. The phase adjuster 3 serving as a passive element contains a region configured in a bulk composition or multiple quantum well. In this region, a band gap is widely set to a degree that a laser oscillation light is not absorbed, and the refractive index of the region is changed in response to the injection of the current or the application of the voltage. The semiconductor optical amplifier 2 and the phase adjuster 3 can be formed by using a well-known butt joint technique or a well-known selection growth technique. The semiconductor optical amplifier 2 and the phase adjuster 3 are sufficiently electrically separated, and a separation resistor of 1 kΩ or more is provided between them. Thus, the currents do not interfere with each other.

The collimating lens 6 is arranged on the side opposite to the optical output side of the semiconductor device 1. The collimating lens 6 converts the light beam from the semiconductor device 1 into a parallel light 14. Then, the light beam parallelized by the collimating lens 6 is reflected by the liquid crystal wavelength tunable mirror 8 and fed back to the semiconductor device 1. The liquid crystal wavelength tunable mirror 8 controls the reflection peak wavelength by applying the voltage to the liquid crystal to change the refractive index of the liquid crystal. The wavelength tunable mirror of such a type is described in, for example, the seventh conventional example.

The etalon 7 is arranged between the collimating lens 6 and the liquid crystal wavelength tunable mirror 8. The etalon 7 has the periodic transmission characteristic with respect to the wavelength in the wavelength band to be used. In this exemplary embodiment, a free spectral range (FSR) of the etalon is 50 GHz. That is, an interval between the transmission peak wavelengths is 50 GHz.

A part of a laser light output 16 which includes a dither signal is branched by a beam splitter 15 to monitor the optical output and supplied to a photo detector (monitor PD17). By this operation, the optical power of the laser light output 16 can be detected from the branch ratio of the beam splitter 15.

The respective elements configuring an external resonator type laser 13 as mentioned above are arranged on a common sub carrier which is not illustrated in FIG. 4, so that the light are straightly propagated. Moreover, a thermistor is arranged at a proper position to monitor a temperature. Moreover, the sub carrier is installed on a temperature controller (Thermo-Electric Cooler: TEC), and this is controlled to a constant temperature by monitoring the thermistor temperature.

The detail of the operation principle of the external resonator type wavelength tunable laser is such as described in the background art, and the liquid crystal wavelength tunable filter is operated as a band pass filter of the light, and the refractive index of the liquid crystal is changed, and consequently its maximum transmission wavelength is changed, thereby attaining the wavelength tunable laser.

The liquid crystal configuring the wavelength tunable mirror is driven with an AC voltage. A liquid crystal particle is inclined in accordance with the amplitude of the AC voltage, and the refractive index in the liquid crystal is changed. In the typical field of display, the liquid crystal is driven with the AC voltage of 50 Hz, and the operation of the liquid crystal is considered to be slow. However, with regard to the frequency response of the liquid crystal, the resonance peak of the liquid crystal is known to be in a range of 100 Hz to 1000 Hz (=1 kHz), although depending on the kind of the liquid crystal. 50 Hz used in the field of a display departs from this resonant frequency. Thus, the liquid crystal substantially remains at rest at a set AC voltage. Even if the AC voltage is changed, the liquid crystal is operated at a low speed.

Here, in this exemplary embodiment, a dithering AC signal having a frequency close to the resonant frequency (1000 Hz in this exemplary embodiment) of the liquid crystal is used as the dither signal for monitoring the state of the liquid crystal. As shown in FIG. 4, an AC driving power supply 19 generates the AC voltage V1 for driving the liquid crystal. A first frequency F1 (=100 kHz) that is the frequency of the AC voltage V1 is set to the value that is sufficiently separated from the resonant frequency of the liquid crystal in the liquid crystal wavelength tunable mirror 8. A first dither signal source 20 generates an AC voltage V2 of a second frequency F2 (=1000 Hz). The AC voltage V2 is sufficiently small as compared with the AC voltage V1. The AC voltage V2 is superimposed on the AC voltage V1 and applied to the liquid crystal wavelength tunable mirror 8.

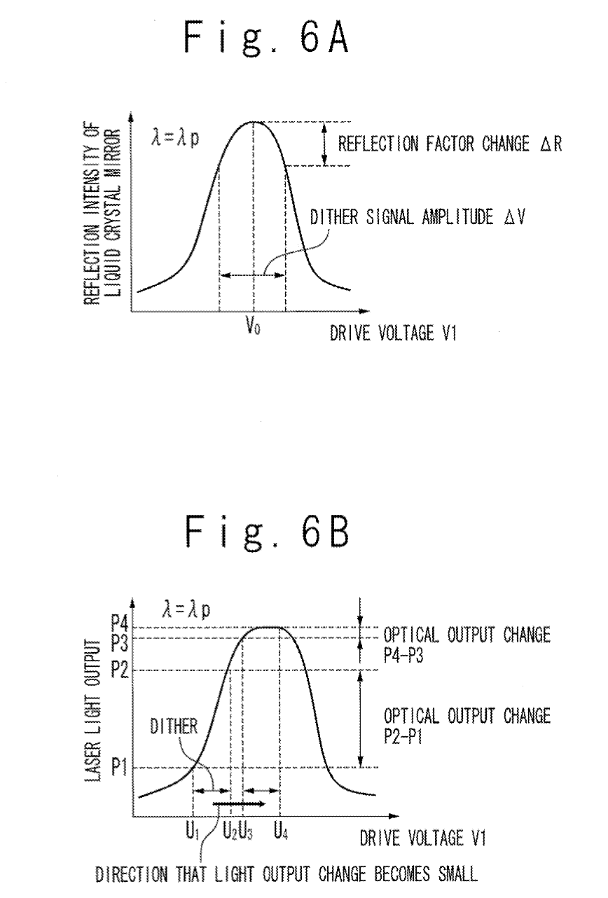

As mentioned above, the liquid crystal molecule is vibrated at the dither signal frequency F2 (1000 Hz) with the angle determined by the amplitude of the AC voltage V1 as a center, namely, this sets the state in which the refractive index of the liquid crystal is modulated. As a result, as shown in FIG. 6A, the reflectivity of this liquid crystal wavelength tunable mirror 8 is varied. When the reflectivity of this liquid crystal wavelength tunable mirror 8 is varied at the second frequency F2, the second frequency F2 of the laser light output 16 is also varied at the second frequency F2.

A control method of maximizing the reflectivity of the wavelength tunable mirror will be described below with reference to FIG. 6B. When the voltage of the dithering AC signal is varied between a voltage U1 and a voltage U2 which are away from the peak of the laser light output, a component that is varied by the dither signal included in the laser light output correspondingly thereto is great. In such a case, if the control is performed such that the voltage of the dither signal is changed between a voltage U3 and a voltage U4, the component that is varied by the dither signal included in the laser light output becomes smaller. In this way, when the liquid crystal drive voltage V1 is controlled to minimize the amplitude of oscillation due to the dither signal included in the laser light output, it can be consequently controlled to the drive voltage at which the reflectivity of the wavelength tunable mirror becomes maximum. The foregoing control can be performed because a part of the laser light output 16 is monitored by the monitor PD17 and then a signal of the frequency F2 is sampled by the DSP 30 and further its amplitude is read.

With such a control mechanism, even if the environment temperature is changed, or even if the aged deterioration changes the characteristics of the wavelength tunable mirror to increase the drive AC voltage, the maximum reflection wavelength of the wavelength tunable mirror can continue to coincide with the laser oscillation wavelength. Also, the laser optical output is kept, and the precision of the laser oscillation wavelength is kept high.

Also, in FIG. 4, when the optical output signal is monitored, an first electric band pass filter 18 is inserted to minimize the crosstalk between frequency signals, thereby allowing only the signal of the second frequency F2 to be separated. Thus, the control becomes easy. It should be noted that the signal of the first frequency F1 is used to drive the liquid crystal. Thus, the signal of the first frequency F1 is not required to be monitored.

Also, the first frequency F1 and the second frequency F2 are desired to be sufficiently separated. The frequency F2 should be close to the resonant frequency of the liquid crystal. From the reason that the first frequency F1 for the basic drive is desired to be set to a value as far as possible from the resonant frequency (between 100 and 1000 Hz), it may be set to the frequency side higher than 100 Hz. In this case, the large and small relation between the two frequencies is desired to be defined as F2<F1.

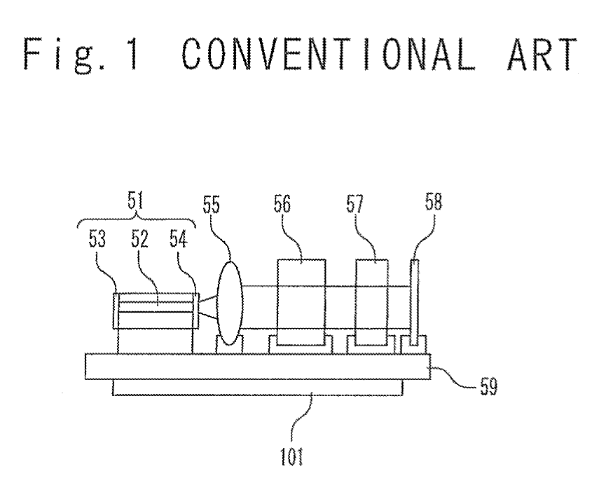

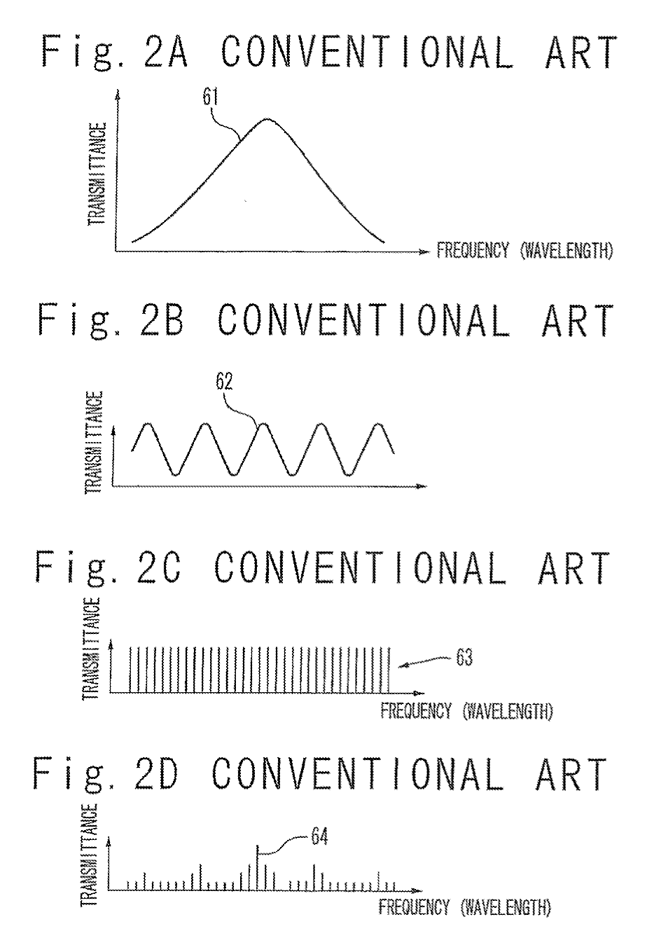

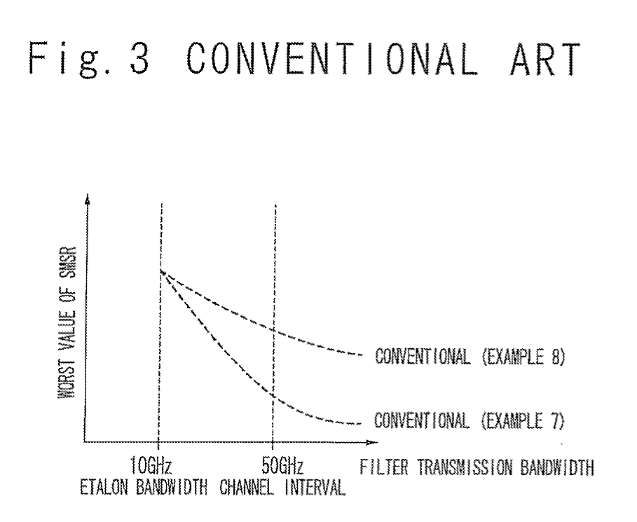

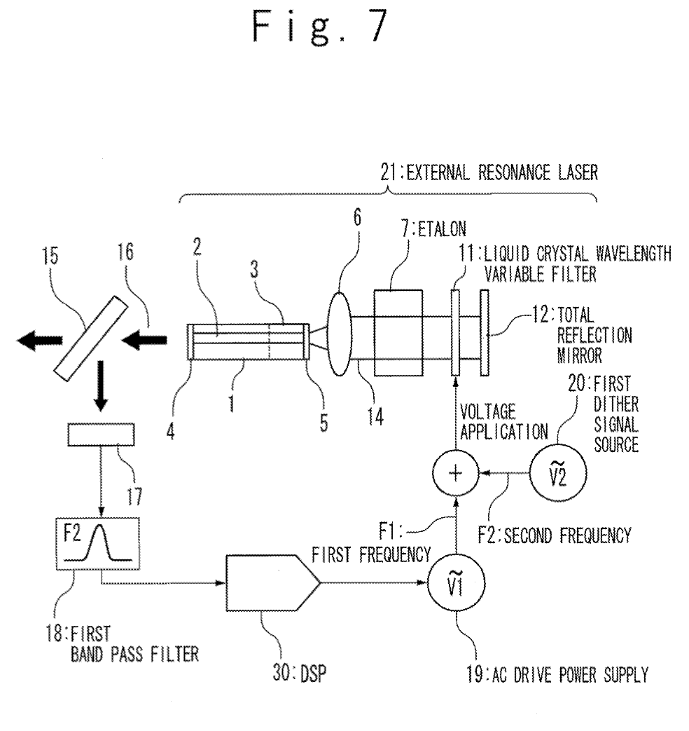

Also, as a modification of this exemplary embodiment, the configuration of the external resonator type wavelength tunable laser as shown in FIG. 7 can be designed by using a wavelength tunable filter 11 using the liquid crystal described in the ninth conventional example and a total reflection mirror 12, instead of the wavelength tunable mirror. Similarly to FIG. 1, the light beam generated by the semiconductor device 1 is converted into the parallel light by the collimating lens 6. The light beam parallelized by the collimating lens 6 is transmitted through the wavelength tunable filter 10 and then reflected by the total reflection mirror 12 so as to be fed back to the original semiconductor device 1. Even in this case, similarly to the wavelength tunable mirror in this exemplary embodiment, the similar effect can be obtained by feedback-controlling the wavelength tunable filter 10.

### Second Exemplary Embodiment

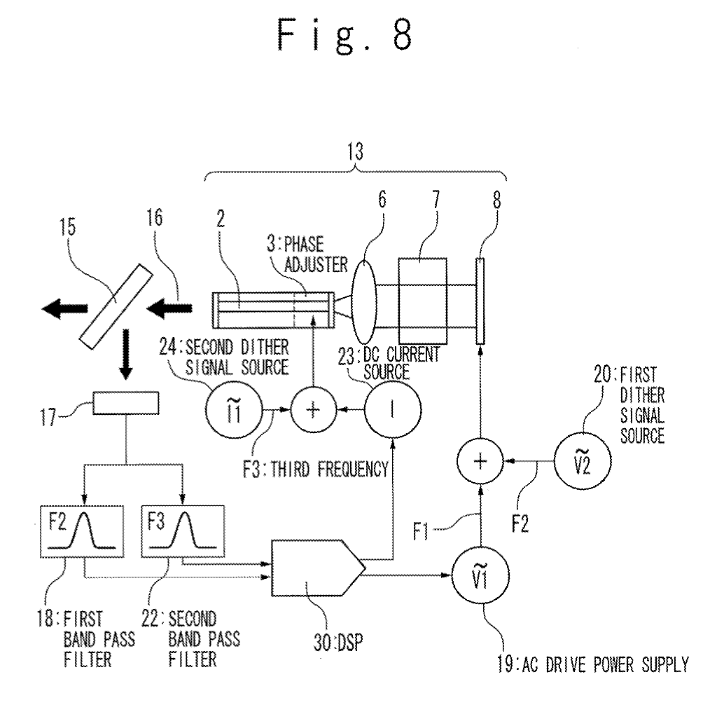

The second exemplary embodiment of the present invention will be described below. FIG. 8 is a block diagram showing a configuration of the external resonator type wavelength tunable laser apparatus and a control apparatus which are according to the second exemplary embodiment of the present invention, and the same symbols or reference numerals are assigned to the same components as in FIG. 4. The external resonator type wavelength tunable laser apparatus in this exemplary embodiment contains the semiconductor device 1 including the semiconductor optical amplifier 2, the collimating lens 6, the etalon 7, and the wavelength tunable mirror 8 whose transmission characteristic is not periodic inside the wavelength band to be used. The semiconductor device 1 is formed by integrating a gain region 2 and the phase adjuster 3. Usually, a DC current is applied to the phase adjuster 3 so as to perform the phase adjustment. However, in this exemplary embodiment, since AC current is also superimposed on the current for the phase adjustment, the dither control is carried out.

In this exemplary embodiment, as shown in FIG. 8, the AC driving power supply 19 generates a basic drive AC voltage V1. The first frequency F1 as the frequency of the basic drive AC voltage V1 is set to the value F1=100 kHz that is sufficiently far from the resonant frequency. The first dither signal source 20 generates the AC voltage V2 of the second frequency F2=100 Hz as the dither signal. The AC voltage V2 is superimposed on the basic drive AC voltage V1 and applied to the liquid crystal wavelength tunable mirror 8. The liquid crystal molecule is vibrated by the dither signal F2 (100 Hz) by employing an angle determined by the amplitude of the drive AC voltage V1 as a center. That is, the refractive index of the liquid crystal is modulated. As a result, similarly to the first exemplary embodiment, as shown in FIG. 6A, the reflectivity of the liquid crystal wavelength tunable mirror 8 is varied. When the reflectivity of this liquid crystal wavelength tunable mirror 8 is varied at the second frequency F2, the laser light output 16 is also varied at the second frequency F2. Thus, as shown in FIG. 6B, when the liquid crystal drive voltage V1 is controlled such that the amplitude resulting from the dither signal included in the laser light output is minimized, it can be controlled to the drive voltage in which the reflectivity of the wavelength tunable mirror becomes maximum.

In this exemplary embodiment, the DC current generated by a DC current source 23 is added as a signal for adjusting the phase to the phase adjuster 3 integrated in the semiconductor. A second dither signal source 24 generates the dither signal of a third frequency F3 differing from the frequencies F1 and F2. The dither signal is superimposed on the DC current generated by the DC current source 23 and applied to the phase adjuster 3. Since the dither signal is applied, the optical output of the laser is modulated at the third frequency F3. A part of the optical output of the laser is converted into an electric signal by the monitor PD 17. Of the electric signal, a component close to the third frequency F3 is separated and monitored by a second band pass filter 22. This operation can control the DC current value for the phase adjustment so that the amplitude of the signal of the frequency F3 becomes minimum, similarly to the first exemplary embodiment. Thus, the laser oscillation wavelength can be made coincident with the transmission peak wavelength of the etalon 7 in a better precision. In this exemplary embodiment, the third frequency is defined as F3=1000 Hz (1 kHz).

In this exemplary embodiment, the signals of the first frequency F1, the second frequency F2 and the third frequency F3 are applied at the same time. The reason why the frequencies F1 and F2 superimposed for the liquid-crystal must be separated as far as possible is similar to the first exemplary embodiment. However, since the dither signal of the third frequency F3 is applied to the phase adjustment region 3 on the semiconductor device, there is no relation to the crosstalk inside the liquid crystal. Thus, if the respective frequency signals can be separated from the optical output signal, there is no special limit on the third frequency F3. However, in view of the practical use, since the frequency F1 and the frequency F2 are sufficiently far, the frequency F3 is desired to be selected as a frequency between the frequencies F1 and F2. In this case, if F1>F2 in the first exemplary embodiment can be established, F1>F3>F2 can be established. In this exemplary embodiment, F1=100 kHz, F2=100 Hz, and F3=1000 Hz.

Also, as a modification of this exemplary embodiment, it is possible to configure the external resonator type wavelength tunable laser that contains the wavelength tunable filter 11 using the liquid crystal described in the ninth conventional example and the total reflection mirror 12 instead of the wavelength tunable mirror 8. This is similar to the external resonator laser structure in FIG. 7. Thus, although not shown, even in that case, the wavelength tunable filter 10 and the phase adjustment region are feedback-controlled as described in this exemplary embodiment. Therefore, the similar effect can be obtained.

### Third Exemplary Embodiment

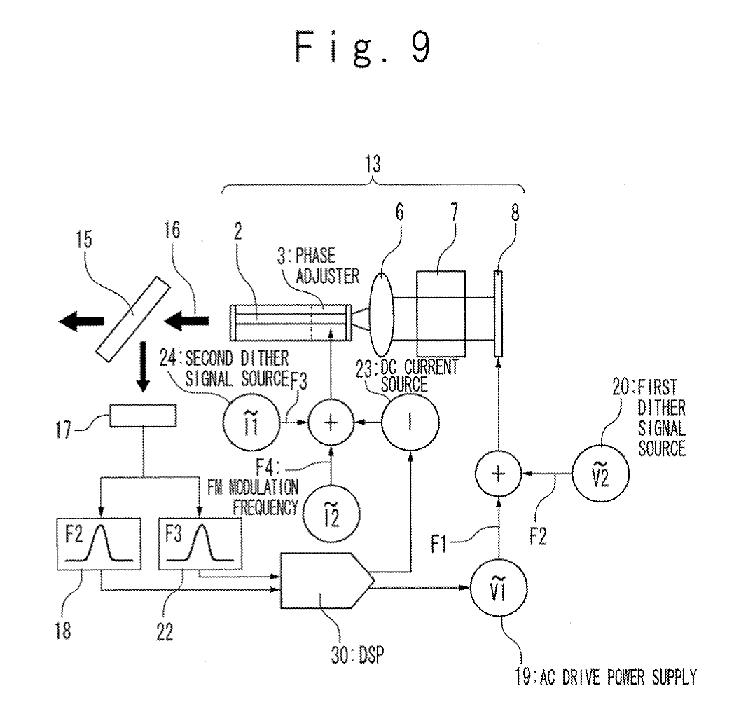

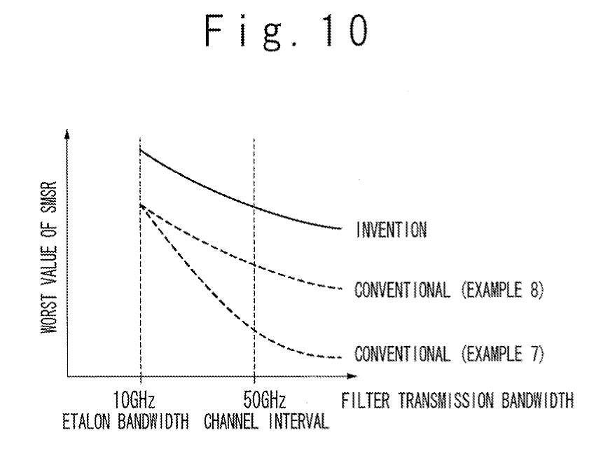

The third exemplary embodiment of the present invention will be described below. FIG. 9 is the block diagram showing the configuration of the external resonator type wavelength tunable laser apparatus and control apparatus in the third exemplary embodiment of the present invention. The same symbols assigned to the elements equal to the elements shown in FIG. 4. In this exemplary embodiment, in addition to the second exemplary embodiment, a fourth frequency F4 is superimposed on the phase adjustment region 3. The frequency F4 is a free running signal for suppressing a stimulated brillouin scattering (SBS) in an optical fiber transmission, and is not used to control.

In this exemplary embodiment, as shown in FIG. 9, the first frequency F1 as the frequency of the basic drive AC voltage V1 is set to the frequency F1=100 kHz that is sufficiently-far from the resonant frequency of the liquid crystal, and the AC voltage V2 of the second frequency F2=100 Hz generated by the first dither signal source 20 is superimposed thereon and applied to the liquid crystal wavelength tunable mirror 8. The second dither signal source 24 generates and applies a dither signal of the third frequency F3=1000 Hz to the phase adjustment current for controlling the phase adjustment in the phase adjuster 3. The operation described hereinbefore is similar to the second exemplary embodiment. Since the liquid crystal is vibrated at 100 Hz with the angle determined by the amplitude of the drive AC voltage V1 as a center, the refractive index of the liquid crystal is modulated. As a result, similarly to the first exemplary embodiment, as shown in FIG. 6A, the reflectivity of this liquid crystal wavelength tunable mirror 8 is varied. When the reflectivity of this liquid crystal wavelength tunable mirror 8 is varied at the second frequency F2, the laser light output 16 is also varied at the second frequency F2. Thus, as shown in FIG. 6B, since the liquid crystal drive voltage V1 is controlled to minimize the amplitude of the dither signal included in the laser light output, the reflectivity of the wavelength tunable mirror becomes maximum. Moreover, since the DC current for the phase adjustment can be controlled to minimize the amplitude of the signal of the frequency F3, the laser oscillation wavelength can be made coincident with the transmission peak wavelength of the etalon 7 at the better precision.

Typically, in an optical fiber communication, when a signal of the laser light whose spectral line width is narrow is propagated, the optical loss increases due to the influence of the stimulated brillouin scattering (SBS) inside the optical fiber, and the transmission distance is limited. For this reason, in the optical fiber communication in recent years, it is possible to decrease the optical loss inside the optical fiber by intentionally FM-modulating the laser oscillation wavelength and consequently suppressing the SBS inside the optical fiber. However, when the periodic channel selecting filter is used, the FM modulation efficiency decreases, which cannot suppress the SBS. For this reason, the increase in loss inside the optical fiber became problematic in a long distance communication.

In this exemplary embodiment, a signal of a fourth frequency F4 different from the frequencies F1, F2 and F3 is superimposed for the phase adjustment region 3 in the semiconductor device 1, and the FM modulation is performed on the laser oscillation wavelength by an FM modulation signal generated by an FM modulation signal generator 31. Here, the signal of F4=10 kHz is used. The laser oscillation wavelength is FM-modulated by this signal of the fourth frequency F4. However, the signal of the frequency F4 is free running, and the feedback control is not required to be especially performed therewith. Thus, it is possible to suppress the SBS inside the optical fiber and elongate the optical fiber transmission distance.

In this exemplary embodiment, the signals of the first frequency F1, the second frequency F2, the third frequency F3 and the fourth frequency F4 are applied at the same time. The reason why the frequencies F1 and F2 of the signal superimposed for the liquid crystal must be separated as far as possible is similar to the first exemplary embodiment. As for the dither signal of the third frequency F3, if the respective frequency signals can be separated from the optical output signal, there is no special limit on the third frequency F3 and this is similar to the second exemplary embodiment. As for the fourth frequency F4, the high frequency that is effective for the SBS suppression is typically desirable, and 10 kHz is used in this exemplary embodiment. However, those frequencies F1 to F4 signals are desired to be separated from each other because the crosstalk is desired to be as small as possible. In the second exemplary embodiment, F1>F3>F2. However, as for the frequency F4, F4>F3 is desirable. Thus, as described in this exemplary embodiment, F1>F4>F3>F2 (F1=100 kHz, F2=100 Hz, F3=1000 Hz and F4=10 kHz) is defined, or F4>F1>F3>F2 (F1=10 kHz, F2=100 Hz, F3=1000 Hz and F4=100 kHz) is desirable.

Also, in this exemplary embodiment, it is possible to configure the external resonator type wavelength tunable laser that contains the wavelength tunable filter 11 using the liquid crystal as described in the ninth conventional example and the total reflection mirror 12 instead of the wavelength tunable mirror 8. This is similar to the external resonator laser structure shown in FIG. 7. Thus, although not shown, even in this case, since the wavelength tunable filter 10 and the phase adjustment region are feedback-controlled as described in this exemplary embodiment, the similar effect can be obtained.

It should be noted that in the first to third exemplary embodiments, the digital signal processor (DSP) 30 is used to process the optical output signal. The DSP can sample the signal to be monitored at the high rate and consequently execute the digital signal process thereon in the waveform including the phase data inside the DSP. Also, the control based on the DSP is suitable for monitoring and processing the plurality of different frequency signals.

Also, in the first to third exemplary embodiments, the respective frequencies are desired to be separated by the respective band pass filters, after received by the monitor PD 17. Because of the characteristics of the usually-used band pass filter, the respective frequencies are desired to be separated by one digit or more. Consequently, the more stable control can be attained.

Also, in the first to third exemplary embodiments, by using the control circuit of the present invention, it is possible to use the wavelength tunable mirror that has the transmission bandwidth wider than the wavelength channel interval of 50 GHz. By using the wavelength tunable mirror that has the wavelength bandwidth equal to or wider than the channel interval to be used, it is possible to increase the manufacturing yield of the wavelength tunable mirror and attain the external resonator type wavelength tunable laser in a low cost.

Also, in the eighth conventional example, since the laser resonator length is set, the laser mode is adjusted to the asynchronous mode. In the first to third exemplary embodiments, by setting the resonator length of the laser, similarly, it is possible to set the laser mode to the asynchronous mode. Consequently, the mode can be further stabilized.

It should be noted that in the first to third exemplary embodiments, an adjusting mechanism for controlling even the current supplied to the gain region 2 and adjusting a laser light output amount may be provided. In this case, a photo detector can be used to carry out a usual APC (Auto Power Control) control so that the optical output becomes a constant setting value.

The present invention can be applied to a middle or long distance light source for the wavelength multiplexing communication that is used in a long haul group, a metro group and an access group.

1-14. (canceled)

15. An external resonator type wavelength tunable semiconductor laser apparatus comprising:
a semiconductor laser;
a external resonator configured to resonate a laser beam outputted from said semiconductor laser,
wherein said external resonator comprises a wavelength tunable mirror or wavelength tunable filter, including liquid crystal which is arranged in an optical path of said laser beam and changes a refractive index in response to an applied voltage;
a dither signal generating section configured to generate a dither signal of a second frequency F2 close to a resonant frequency of said liquid crystal;
an AC drive power supply configured to generate a refractive index control signal of a first frequency F1 in which an absolute value of a difference from said resonant frequency is larger than said second frequency F2, and superimpose said dither signal and said refractive index control signal to apply to said wavelength tunable mirror or said wavelength tunable filter; and
a control unit configured to detect a light output of said laser beam, and perform a feedback control to control an amplitude of a voltage generated by said AC drive power supply such that the amplitude of a component of said dither signal contained in said light output is minimized.

16. The external resonator type wavelength tunable semiconductor laser apparatus according to claim 15, wherein said external resonator type wavelength tunable semiconductor laser apparatus supplies said laser beam to an optical fiber of an optical communication system which has a plurality of channels which are set in a predetermined frequency interval, and
a transmission bandwidth of said wavelength tunable mirror or wavelength tunable filter is wider than an interval between adjacent two of said plurality of channels.

17. The external resonator type wavelength tunable semiconductor laser apparatus according to claim 16, wherein the transmission bandwidth of said wavelength tunable mirror or wavelength tunable filter is equal to or more than 50 GHz.

18. The external resonator type wavelength tunable semiconductor laser apparatus according to claim 15, wherein the frequency F1 is larger than the frequency F2.

19. The external resonator type wavelength tunable semiconductor laser apparatus according to claim 15, further comprising:
a phase adjusting section configured to adjust a phase of said laser beam in response to an input electrical signal;
a DC current generating section configured to generate a DC current and supply to said phase adjusting section as said input electrical signal; and
a dither signal supplying section configured to generate an electric current to convey a second dither signal of a third frequency F3 which is different from the frequencies F1 and F2 to supply to said phase adjusting section.

20. The external resonator type wavelength tunable semiconductor laser apparatus according to claim 19, further comprising:
an etalon configured to convert said laser beam which is resonated by said external resonator, into a light signal of a discrete channel,
wherein a mirror provided for said external resonator to reflect said laser beam is arranged at a position where said laser beam of adjacent channel does not resonate in said external resonator, when the light signal of a predetermined channel of said discrete channels is generated in said external resonator.

21. The external resonator type wavelength tunable semiconductor laser apparatus according to claim 20, wherein the frequencies F1, F2 and F3 satisfy the following relation F2<F3<F1.

22. The external resonator type wavelength tunable semiconductor laser apparatus according to claim 19, wherein the frequencies F1, F2 and F3 are different each other by 10 times or more.

23. The external resonator type wavelength tunable semiconductor laser apparatus according to claim 15, further comprising:
a phase adjusting section configured to adjust a phase of said laser beam in response to an inputted electrical signal; and
an FM modulating section configured to supply an FM modulation signal of the fourth frequency F4 to said phase adjusting section and modulate the wavelength of said laser beam.

24. The external resonator type wavelength tunable semiconductor laser apparatus according to claim 23, wherein a feedback control is not performed by said FM modulation signal.

25. The external resonator type wavelength tunable semiconductor laser apparatus according to claim 23, further comprising:
a phase adjusting section configured to adjust the phase of said laser beam in response to the input electrical signal;
a DC current generating section to generate a DC current and supply said phase adjusting section as said input electrical signal; and
a dither signal supplying section configured to generate an electric current to convey a second dither signal of a third frequency F3 which is different from the frequencies F1 and F2 to supply to said phase adjusting section,
wherein the frequencies F1, F2, F3 and F4 satisfy the following relation of F2<F3<F4<F1 or F2<F3<F1<F4.

26. The external resonator type wavelength tunable semiconductor laser apparatus according to claim 25, wherein the frequencies F1, F2, F3 and F4 are different each other by 10 times or more.

27. The external resonator type wavelength tunable semiconductor laser apparatus according to claim 15, wherein said feedback control is performed by a digital signal processor.

28. The external resonator type wavelength tunable semiconductor laser apparatus according to claim 15, further comprising:
an optical amplifier configured to amplify said laser beam;
an output light detecting section configured to detect a light output by the output light signal which is resonated by said external resonator and is outputted from said external resonator type wavelength tunable semiconductor laser apparatus; and
an output light negative feed-back control unit configured to control said light amplifier such that the detected light output is kept constant.
